(19) United States
(12) Patent Application Publication
(10) Pub. No.: US 2026/0068663 A1
(43) Pub. Date: Mar. 5, 2026

(54) SEMICONDUCTOR MODULE ARRANGEMENT, AND METHODS FOR PRODUCING SEMICONDUCTOR MODULE ARRANGEMENTS

(71) Applicant: Infineon Technologies AG, Neubiberg (DE)

(72) Inventors: Elena Zwar, Dortmund (DE); Thomas Dütemeyer, Soest (DE)

(73) Assignee: Infineon Technologies AG, Neubiberg (DE)

(21) Appl. No.: 19/296,070

(22) Filed: Aug. 11, 2025

(30) Foreign Application Priority Data
Aug. 30, 2024 (DE) 102024124817.3

(51) Int. Cl. H01L 23/373; H01L 21/48

(52) U.S. Cl. CPC H01L 23/3737

(57) ABSTRACT

A semiconductor module arrangement comprises a substrate (10), a base plate or heat sink (30), and a layer (40) arranged between the substrate (10) and the base plate or heat sink (30), wherein the layer (40) comprises a liquid or viscous thermal interface material, TIM, (42) a plurality of filler particles (44) distributed within the liquid or viscous thermal interface material, TIM, (42) and a plurality of capsules (46) distributed within the liquid or viscous thermal interface material, TIM, (42) wherein each of the plurality of capsules (46) comprises a catalyst, or radical initiator, and the plurality of capsules (46) are configured to release the catalyst, or radical initiator when being activated, wherein the plurality of capsules (46) are configured to be activated at increased temperatures or under increased pressure.

### TECHNICAL FIELD

The instant disclosure relates to a semiconductor module arrangement, and to methods for producing semiconductor module arrangements.

### BACKGROUND

Power semiconductor module arrangements usually include at least one substrate. The substrate may be arranged on a base plate or a heat sink. A semiconductor arrangement including a plurality of semiconductor components (e.g., diodes, MOSFETs, JFETs, HEMTs, IGBTs, or any other suitable controllable or non-controllable semiconductor elements in a parallel, half-bridge, or any other configuration) is usually arranged on at least one of the at least one substrate. Each substrate usually comprises a substrate layer (e.g., a ceramic layer), a first metallization layer deposited on a first side of the substrate layer and a second metallization layer deposited on a second side of the substrate layer. The semiconductor components are mounted, for example, on the first metallization layer. The second metallization layer may be attached to a base plate or heat sink.

Heat that is generated by the semiconductor components is dissipated through the substrate to the base plate or heat sink. A heat-conducting layer is usually arranged between the substrate and the base plate or heat sink to effectively conduct the heat away from the substrate. A liquid or viscous heat-conducting layer is able to perfectly adapt to any surface and to any irregularities such that there are no significant air pockets between the substrate and the base plate or heat sink which may negatively affect the heat transfer. Liquid heat-conducting layers, however, may unintentionally be “pumped out” from between the substrate and the base plate or heat sink during operation of the semiconductor module, due to the heat changes occurring during the operation of the semiconductor module arrangement. Even further, liquid heat-conducting layers may unintentionally dry out over the lifetime of the semiconductor module such that heat can longer be effectively transferred away from the substrate. As an alternative to liquid heat-conducting layers, sheet materials are also often used for heat-conducting layers. A layer of sheet material, however, is usually comparably thick, difficult to apply, and expensive. Even further, sheet materials are generally not able to perfectly adapt to any surfaces and irregularities.

There is a need for a semiconductor module arrangement which is easy to produce at low costs, which provides for a good thermal conductivity between the substrate and the base plate or heat sink and which has an increased lifetime.

### SUMMARY

A power semiconductor module arrangement includes a substrate, a base plate or heat sink, and a layer arranged between the substrate and the base plate or heat sink, wherein the layer includes a liquid or viscous thermal interface material, TIM, a plurality of filler particles distributed within the liquid or viscous thermal interface material, TIM, and a plurality of capsules distributed within the liquid or viscous thermal interface material, TIM, wherein each of the plurality of capsules includes a catalyst, or radical initiator, and the plurality of capsules are configured to release the catalyst, or radical initiator when being activated.

A method according to embodiments of the disclosure includes arranging a layer between a substrate and a base plate or heat sink of a semiconductor module arrangement, wherein the layer includes a liquid or viscous thermal interface material, TIM, a plurality of filler particles distributed within the liquid or viscous thermal interface material, TIM, and a plurality of capsules distributed within the liquid or viscous thermal interface material, TIM, wherein each of the plurality of capsules includes a catalyst, or radical initiator, and the plurality of capsules are configured to release the catalyst, or radical initiator when being activated.

A method according to further embodiments of the disclosure includes forming a first sub-layer on a surface of one of a substrate and a base plate or heat sink, the first sub-layer including a liquid or viscous thermal interface material, TIM, and a plurality of filler particles distributed within the liquid or viscous thermal interface material, TIM, forming a second sub-layer on a surface of the respective other one of the substrate and the base plate or heat sink, the second sub-layer including a catalyst, or radical initiator, and arranging the substrate on the base plate or heat sink with the first sub-layer and the second sub-layer arranged between the substrate and the base plate or heat sink such that the first sub-layer and the second sub-layer directly contact each other.

The invention may be better understood with reference to the following drawings and the description. The components in the figures are not necessarily to scale, emphasis is instead being placed upon illustrating the principles of the invention. Moreover, in the figures, like reference numerals designate corresponding parts throughout the different views.

### BRIEF DESCRIPTION OF THE DRAWINGS

FIG. 1 schematically illustrates a cross-sectional view of a semiconductor module arrangement.

FIG. 2 schematically illustrates a cross-sectional view of a section of the semiconductor substrate arrangement of FIG. 1.

FIG. 3 schematically illustrates a method for producing a semiconductor module arrangement according to embodiments of the disclosure.

FIG. 4, including FIGS. 4A and 4B, schematically illustrates further steps of a method for producing a semiconductor module arrangement according to embodiments of the disclosure.

FIG. 5 schematically illustrates a method according to further embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. A semiconductor body as described herein may be made from (doped) semiconductor material and may be a semiconductor chip or be included in a semiconductor chip. A semiconductor body has electrically connecting pads and includes at least one semiconductor element with electrodes.

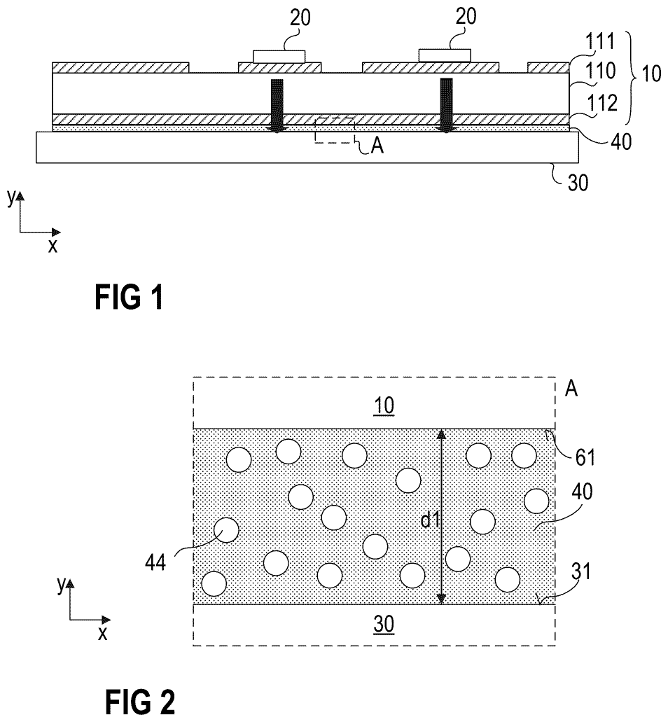

FIG. 1 exemplarily illustrates a semiconductor module arrangement comprising a substrate 10. The substrate 10 includes a dielectric insulation layer 110, a (structured) first metallization layer 111 attached to the dielectric insulation layer 110, and a second metallization layer 112 attached to the dielectric insulation layer 110. The dielectric insulation layer 110 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. Optionally, the first and/or second metallization layer 111, 112 may be covered by a thin layer of nickel or silver, for example. Such a layer may be formed using a nickel plating process or a silver plating process, for example. The substrate 10 may be a ceramic substrate, that is, a substrate in which the dielectric insulation layer 110 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 110 may consist of or include one of the following materials: Al₂O₃, AlN, or Si₃N₄. For instance, the substrate 10 may, e.g., be a Direct Copper Bonding (DCB) substrate, a Direct Aluminum Bonding (DAB) substrate, or an Active Metal Brazing (AMB) substrate.

Usually one or more semiconductor bodies 20 are arranged on a substrate 10. Each of the semiconductor bodies 20 arranged on a substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable or non-controllable semiconductor element. One or more semiconductor bodies 20 may form a semiconductor arrangement on the substrate 10. In FIG. 1, two semiconductor bodies 20 are exemplarily illustrated. Any other number of semiconductor bodies 20, however, is also possible.

In the example illustrated in FIG. 1, the substrate 10 is attached to a base plate or heat sink 30 with the second metallization layer 112 arranged between the dielectric insulation layer 110 and the base plate or heat sink 30. A layer 40 of heat-conducting material is arranged between the second metallization layer 112 and the base plate or heat sink 30. Heat that is generated by the semiconductor bodies 20 may be dissipated through the substrate 10 and the layer 40 of heat-conducting material to the base plate or heat sink 30. This is exemplarily illustrated by the bold arrows in FIG. 1. The second metallization layer 112 of the substrate 10 in FIG. 1 is a continuous layer. The first metallization layer 111 is a structured layer in the arrangement illustrated in FIG. 1. “Structured layer” in this context means that the first metallization layer 111 is not a continuous layer, but includes recesses between different sections of the layer. Such recesses are schematically illustrated in FIG. 1. The first metallization layer 111 in this arrangement exemplarily includes four different sections. Different semiconductor bodies 20 may be mounted to the same or to different sections of the first metallization layer 111. Different sections of the first metallization layer 111 may have no electrical connection or may be electrically connected to one or more other sections using electrical connections such as, e.g., bonding wires. Electrical connections may also include bonding ribbons, connection plates or conductor rails, for example, to name just a few examples. The first metallization layer 111 being a structured layer, however, is only an example. It is also possible that the first metallization layer 111 be a continuous layer. According to another example, the substrate 10 may only comprise a dielectric insulation layer 110 and a first metallization layer 111. The second metallization layer 112 may be a continuous layer or a structured layer. The second metallization layer 112, however, may also be omitted.

The base plate or heat sink 30 may comprise or consist of a metal.

According to one example, the base plate or heat sink 30 comprises or consists of at least one of Al and Cu. According to another example, the base plate or heat sink 30 may be a metal matrix composite (MMC) base plate comprising an MMC material such as AlSiC. Any other suitable materials are possible. The base plate or heat sink 30, optionally, may also be covered by a thin layer of nickel or silver, for example. Such a layer may be formed using a nickel plating process or a silver plating process, for example.

Materials that are used for known heat-conducting layers 40 generally have a very low thermal conductivity which may not be satisfactory for certain applications. Therefore, in order to further increase the thermal conductivity of the layer 40, thermally conductive filler particles 44 may be added to the layer 40. This is schematically illustrated in FIG. 2, which shows a section A of the semiconductor module arrangement of FIG. 1.

The thermally conductive filler particles 44 that may be added to the layer 40 of heat-conducting material may be (evenly) distributed within the layer 40. The thermal conductivity of the filler particles 44 may be greater than the thermal conductivity of the surrounding material of the heat-conducting layer 40. For example, the filler particles 44 may have a thermal conductivity of between 60 and 400 W/mK, such that the resulting layer 40 with filler particles 44 may have a thermal conductivity of between 1 and 10 W/mK. The filler particles 44 may comprise a ceramic material, glass, or a metal powder, for example. A maximum dimension d44 of each of the filler particles 44 may be equal to or less than the thickness d1 of the layer 40. According to one example, a maximum dimension d44 of each of the filler particles 44 may be between 100 nm and 150 μm. The filler particles 44 may all be equally shaped and may all have the same size, as is schematically illustrated in FIG. 2. This, however, is only an example. It is generally possible that the plurality of filler particles 44 comprises a first plurality of particles of a first type, and a second plurality of particles of a second type. The particles of the first type may be smaller or larger in size than the particles of the second type, for example. In the example illustrated in FIG. 2, the filler particles 44 have a round shape. In this case, a maximum dimension d44 of each particle corresponds to a diameter of the respective particle. This, however, is only an example. Generally, each particle of the plurality of filler particles 44 may have any regular or irregular shape.

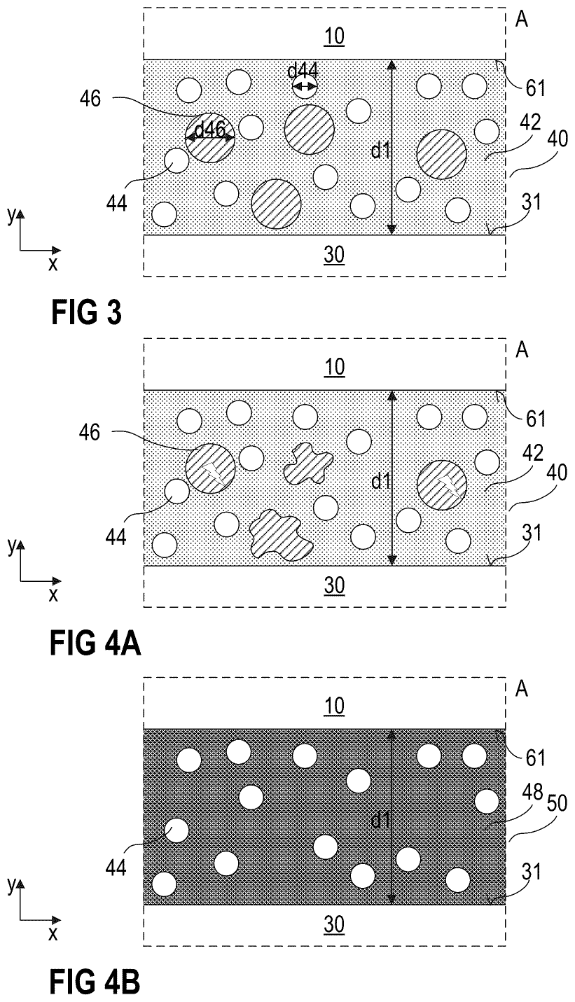

Now referring to FIG. 3, a semiconductor module arrangement and a corresponding method for forming a semiconductor module arrangement according to embodiments of the disclosure are schematically illustrated. The semiconductor module arrangement comprises a substrate 10, a base plate or heat sink 30, and a layer 40 arranged between the substrate 10 and the base plate or heat sink 30. The layer 40, comprises a liquid or viscous thermal interface material, TIM, 42, and, similar to what has been described with respect to FIG. 2 above, a plurality of filler particles 44 distributed within the liquid or viscous thermal interface material, TIM, 42. Each filler particle of the plurality of filler particles 44 may consist of a thermally conductive material, wherein a thermal conductivity of the thermally conductive material is greater than a thermal conductivity of the liquid or viscous thermal interface material, TIM, 42. A thickness d1 of the layer 40 may be between 70 μm and 120 μm, or between 40 μm and 70 μm, for example.

A heat-conducting layer 40 essentially formed by a liquid or viscous thermal interface material, TIM, 42 is able to perfectly adapt to any surface (i.e. surface 61 of substrate 10 and surface 31 of base plate or heat sink 30) and to any irregularities that may be present on the respective surfaces 31, 61 (projections, leads, bumps, gaps, cavities, etc.) such that there are no significant air pockets between the substrate 10 and the base plate or heat sink 30 which may negatively affect the heat transfer between the substrate 10 and the base plate or heat sink 30. A heat-conducting layer 40 of liquid or viscous thermal interface material, TIM, 42, however, may unintentionally be “pumped out” from between the substrate 10 and the base plate or heat sink 30 during operation of the semiconductor module, due to the heat changes occurring during the operation of the semiconductor module arrangement. Even further, heat-conducting layers 40 of liquid or viscous thermal interface material, TIM, 42 may unintentionally dry out over the lifetime of the semiconductor module such that heat can longer be effectively transferred away from the substrate 10.

For this reason, the layer 40 further comprises a plurality of capsules 46 distributed within the liquid or viscous thermal interface material, TIM, 42 wherein each of the plurality of capsules 46 comprises catalyst, or radical initiator. The plurality of capsules 46 are configured to release the catalyst, or radical initiator when being activated.

That is, the layer 40 (i.e. the thermal interface material, TIM, 42) is initially liquid or viscous. In this way, the advantages of liquid or viscous layers fully apply. The layer 40, when arranged between a substrate 10 and a base plate or heat sink 30, as is illustrated in FIG. 3, is able to smoothly contact both the surface 61 of the substrate 10 and the surface 31 of the base plate or heat sink 30. In this way, an optimal contact between the substrate 10 and the layer 40, as well as between the layer 40 and the base plate or heat sink 30 is provided. Upon activation, however, a curing process is initiated. After curing, the layer 40 (i.e. the thermal interface material, TIM, 42) is no longer liquid or viscous. In this way, any unwanted pump-out effects during the operation of the semiconductor module arrangement may be efficiently prevented. The arrangement as illustrated in FIG. 3 shows the layer 40 arranged between the substrate 10 and the base plate or heat sink 30 before activation of the plurality of capsules 46.

Each capsule of the plurality of capsules 46 may be a microcapsule having a diameter d46 of between 10 μm and 50 μm, for example. Other diameters, sizes or shapes, however, are generally also possible. Round microcapsules, however, are generally easy to manufacture. Each capsule of the plurality of capsules 46, in addition to the catalyst or radical initiator, may further comprise a solvent, as well as other small filler particles and/or small quantities of the liquid or viscous thermal interface material. The liquid or viscous thermal interface material, TIM, 42 may comprise a plurality of separate polymer chains. For example, the liquid or viscous thermal interface material, TIM, 42 may comprise one of a silicone base polymer, an epoxy mold or potting compound, or an acrylate. The liquid or viscous thermal interface material, TIM, 42 may further comprise a networker. When the plurality of capsules 46 are activated and release the catalyst or radical initiator, the catalyst or radical initiator distributes within the thermal interface material, TIM, 42, and connects the networker included in the thermal interface material, TIM, 42 with the polymer chains of the thermal interface material, TIM, 42, thereby curing the liquid or viscous thermal interface material, TIM, 42. That is, generally speaking, each of the plurality of capsules 46 comprises a material that, when it is released from the capsule and gets in direct contact with the thermal interface material, TIM, 42, triggers a reaction in which a networker is connected to the polymer chains, and a cross-linked network of chains is formed.

The number of capsules 46 comprised in the layer 40 generally depends on several factors. For example, the number of capsules 46 may depend on the size of each individual capsule and, therefore, the amount of catalyst, or radical initiator included in each capsule. The number of capsules generally also depends on the volume of thermal interface material, TIM, 42 comprised in the layer 40. The number of capsules 46 may further depend on the specific materials that are used, as this also defines an overall amount of catalyst, or radical initiator that is required in order to fully cure the layer 40.

A method for forming a semiconductor module arrangement comprises arranging a layer 40 between a substrate 10 and a base plate or heat sink 30 of a semiconductor module arrangement. The layer 40 comprises a liquid or viscous thermal interface material, TIM, 42, a plurality of filler particles 44 distributed within the liquid or viscous thermal interface material, TIM, and a plurality of capsules 46 distributed within the liquid or viscous thermal interface material, TIM, wherein each of the plurality of capsules 46 comprises catalyst, or radical initiator. The plurality of capsules 46 are configured to release the catalyst, or radical initiator when being activated. The plurality of capsules 46 may be configured to be activated at increased temperatures, increased pressure, or other forms of activation.

Activation of the plurality of capsules 46 may not require any specific additional steps. The plurality of capsules 46 may be configured to be activated at increased temperatures and/or under increased pressure. According to one example, the plurality of capsules 46 are activated when pressing the substrate 10 towards the base plate or heat sink 30, thereby exerting pressure on the layer 40 and on the plurality of capsules 46 comprised in the layer 40. The substrate 10 is usually pressed towards the base plate or heat sink 30 with a certain force when it is arranged on the base plate or heat sink 30 during the mounting process. That is, the plurality of capsules 46 may be activated in the course of arranging the substrate 10 on the base plate or heat sink 30, with the layer 40 arranged between the substrate 10 and the base plate or heat sink 30.

According to another example, the plurality of capsules 46 are activated when heat is generated in the semiconductor module arrangement during operation of the semiconductor module arrangement. As soon as the semiconductor module arrangement is operated for the first time, heat is generated, e.g., by means of the components arranged on the substrate 10 (e.g., semiconductor bodies 20). As has been described above, this heat is transferred through the substrate 10 and the layer 40 towards the base plate or heat sink 30. That is, the layer 40 automatically gets heated during operation of the semiconductor module arrangement. The activation of the plurality of capsules 46 therefore occurs when the layer 40 is heated for the first time. That is, as soon as the semiconductor module arrangement is operated in an application, the layer 40 will cure and unwanted pump-out effects may no longer occur during subsequent operation of the semiconductor module arrangement. The plurality of capsules 46 may be activated at temperatures of above 100° C., or at or above 150° C., for example. Increased temperatures may also accelerate the curing process. Generally, however, many materials are also known that are designed to cure at lower temperatures.

The step of activating the plurality of capsules 46 is schematically illustrated in FIG. 4A. When applying pressure and/or heat, for example, the capsules 46 will break open, and the catalyst or radical initiator will be released, which triggers the curing of the layer 40. As mentioned above, other forms of activation are generally also possible. A resulting, cured layer 50 is schematically illustrated in FIG. 4B. The capsules 46 are no longer present in the cured layer 50. If the plurality of capsules 46, before activation, comprise a solvent, this solvent generally evaporates during the curing (cross-linking) process and is no longer present in the resulting, cured layer 50. The catalyst may be a co-called Pt-catalyst, for example. The resulting cured layer 50 may be a highly networked and solid layer.

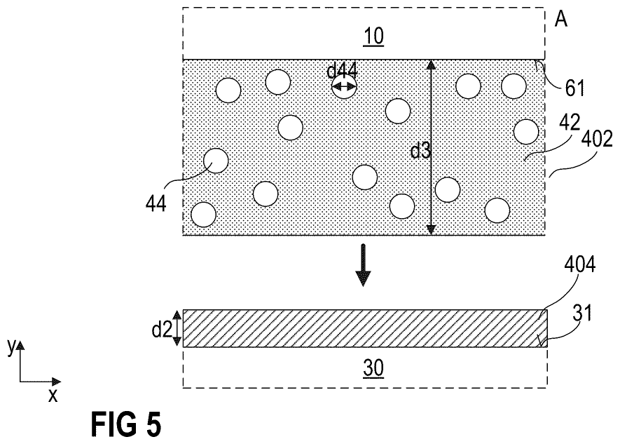

When providing a layer 40 with a plurality of capsules 46 distributed therein as described above, the method and resulting arrangement benefit from both the advantages of liquid or viscous layers (e.g., optimal contact between layer 40 and surfaces 31, 61) and of cured layers (e.g., no pump-out during operation). The same advantages may be achieved, and the same problems may be solved by means of a method according to further embodiments of the disclosure. This method will be described with reference to FIG. 5 in the following.

The alternative method as illustrated in FIG. 5 comprises forming a first sub-layer 402 on a surface 31, 61 of one of a substrate 10 and a base plate or heat sink 30, the first sub-layer 402 comprising a liquid or viscous thermal interface material, TIM, 42 and a plurality of filler particles 44 distributed within the liquid or viscous thermal interface material, TIM, 42. The liquid or viscous thermal interface material, TIM, 42 and the plurality of filler particles 44 distributed within the viscous thermal interface material, TIM, 42 may be similar to what has been described above. Instead of providing a plurality of capsules 46 in the first sub-layer 402, a second sub-layer 404 is formed on a surface 31, 61 of the respective other one of the substrate 10 and the base plate or heat sink 30, the second sub-layer 404 comprising a catalyst, or radical initiator. In the example illustrated in FIG. 5, the first sub-layer 402 is formed on a surface 61 of the substrate 10, and the second sub-layer 404 is formed on a surface 31 of the base plate or heat sink 30. This, however, is only an example. It is also possible that the first sub-layer 402 be formed on a surface 31 of the base plate or heat sink 30, and the second sub-layer 404 be formed on a surface 61 of the substrate 10.

The method further comprises arranging the substrate 10 on the base plate or heat sink 30 with the first sub-layer 402 and the second sub-layer 404 arranged between the substrate 10 and the base plate or heat sink 30 such that the first sub-layer 402 and the second sub-layer 404 directly contact each other. The step of arranging the substrate 10 on the base plate or heat sink 30 is schematically illustrated by means of an arrow in FIG. 5. When the first sub-layer 402 and the second sub-layer 404 contact each other, their materials will blend. This will trigger the curing of the thermal interface material, TIM, 42, similar to what has been described with respect to the activation of the plurality of capsules 46 above.

The first sub-layer 402 and the second sub-layer 404 are both applied to the respective surfaces 31, 61 when they are still liquid or viscous. That is, the first sub-layer 402 and the second sub-layer 404 are both able to perfectly adapt to the respective surfaces (i.e. surface 61 of substrate 10 and surface 31 of base plate or heat sink 30) and to any irregularities that may be present on the respective surfaces 31, 61 (projections, leads, bumps, gaps, cavities, etc.) such that when the substrate 10 is arranged on the base plate or heat sink 30, there are no significant air pockets between the substrate 10 and the base plate or heat sink 30 which may negatively affect the heat transfer. When arranging the substrate 10 in its desired mounting position on the base plate or heat sink 30, however, the materials of the sub-layers 402, 404 get into direct contact with each other. The substrate 10 is usually pressed on the base plate or heat sink 30 with a certain amount of force. In this way the materials of the sub-layers 402, 404 blend, and the curing process is triggered automatically while mounting the substrate 10 on the base plate or heat sink 30. No additional curing steps are required. When the semiconductor substrate arrangement is operated for the first time, the resulting layer is already fully cured, and no pump-out effects may occur.

A thickness d3 of the first sub-layer 402 may be between 70 μm and 120 μm, or between 40 μm and 70 μm, for example. The thickness d1 of the first sub-layer 402 may essentially define the thickness of the resulting cured layer 50. A thickness d2 of the second sub-layer 404 may generally be less than the thickness of the first sub-layer 402. For example, the thickness d2 of the second sub-layer 404 may be less than one half, less than one third, or even less than one fourth of the thickness d3 of the first sub-layer 402. That is, d2<d3/2, or d2<d3/3, or d2<d3/4, for example. This is, because usually a comparably small amount of catalyst, or radical initiator is required in order to fully cure the thermal interface material, TIM, 42.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A semiconductor module arrangement comprising:
a substrate;
a base plate or heat sink; and
a layer arranged between the substrate and the base plate or heat sink, wherein
the layer comprises a liquid or viscous thermal interface material a plurality of filler particles distributed within the liquid or viscous thermal interface material and a plurality of capsules distributed within the liquid or viscous thermal interface material wherein each of the plurality of capsules comprises a catalyst, or radical initiator, and
the plurality of capsules are configured to release the catalyst, or radical initiator when being activated.

2. The semiconductor module arrangement of claim 1, wherein the plurality of capsules are configured to be activated at increased temperatures and/or under increased pressure.

3. The semiconductor module arrangement of claim 1, wherein each capsule of the plurality of capsules is a microcapsule having a diameter of between 10 μm and 50 μm.

4. The semiconductor module arrangement of claim 1, wherein each capsule of the plurality of capsules further comprises a solvent.

5. The semiconductor module arrangement of claim 3, wherein each filler particle of the plurality of filler particles consists of a thermally conductive material, wherein a thermal conductivity of the thermally conductive material is greater than a thermal conductivity of the liquid or viscous thermal interface material.

6. The semiconductor module arrangement of claim 1, wherein a maximum dimension of each filler particle of the plurality of filler particles is between 100 nm and 150 μm.

7. The semiconductor module arrangement of claim 1, wherein a thickness of the layer is between 40 μm and 120 μm.

8. The power semiconductor module arrangement of claim 1, wherein the liquid or viscous thermal interface material comprises a plurality of separate polymer chains.

9. The semiconductor module arrangement of claim 1, wherein the liquid or viscous thermal interface material comprises one of a silicone base polymer, an epoxy mold or potting compound, or an acrylate.

10. The semiconductor module arrangement of claim 9, wherein the liquid or viscous thermal interface material further comprises a networker.

11. A method comprising
arranging a layer between a substrate and a base plate or heat sink of a semiconductor module arrangement, wherein
the layer comprises a liquid or viscous thermal interface material, a plurality of filler particles distributed within the liquid or viscous thermal interface material and a plurality of capsules (46) distributed within the liquid or viscous thermal interface material, wherein each of the plurality of capsules (46) comprises a catalyst, or radical initiator, and
the plurality of capsules are configured to release the catalyst, or radical initiator when being activated, wherein the plurality of capsules are configured to be activated.

12. The method of claim 11, further comprising activating the plurality of capsules by applying increased temperature.

13. The method of claim 12, wherein the plurality of capsules are activated when heat is generated in the semiconductor module arrangement during operation of the semiconductor module arrangement.

14. The method of claim 11, further comprising activating the plurality of capsules by applying increased pressure.

15. The method of claim 14, wherein the plurality of capsules are activated when pressing the substrate towards the base plate or heat sink, thereby exerting pressure on the layer and on the plurality of capsules comprised in the layer.

16. The method of claim 11, wherein the liquid or viscous thermal interface material comprises a plurality of separate polymer chains and a networker, and, when the plurality of capsules release the catalyst or radical initiator, the catalyst or radical initiator connects the networker with the polymer chains, thereby curing the liquid or viscous thermal interface material.

17. A method comprising
forming a first sub-layer on a surface of one of a substrate and a base plate or heat sink, the first sub-layer comprising a liquid or viscous thermal interface material and a plurality of filler particles (44) distributed within the liquid or viscous thermal interface material;
forming a second sub-layer on a surface of the respective other one of the substrate and the base plate or heat sink, the second sub-layer comprising a catalyst, or radical initiator; and
arranging the substrate on the base plate or heat sink with the first sub-layer and the second sub-layer arranged between the substrate and the base plate or heat sink such that the first sub-layer and the second sub-layer directly contact each other.
